(19) United States
(12) Patent Application Publication
(10) Pub. No.: US 2025/0254873 A1
(43) Pub. Date: Aug. 7, 2025

(54) STAIRCASE STRUCTURES AND METHODS FOR FORMING THE SAME

(71) Applicant: Yangtze Memory Technologies Co., Ltd., Wuhan (CN)

(72) Inventors: Meng XIAO, Wuhan (CN); Kuan DONG, Wuhan (CN); Longdong LIU, Wuhan (CN); Zhou HE, Wuhan (CN); Gang ZHANG, Wuhan (CN)

(21) Appl. No.: 18/603,087

(22) Filed: Mar. 12, 2024

(30) Foreign Application Priority Data
Feb. 4, 2024 (CN) 202410161447.0

(51) Int. Cl. H10B 43/27

(52) U.S. Cl. CPC H10B 43/27

(57) ABSTRACT

Systems, devices, and methods for fabricating staircase structures in three-dimensional (3D) semiconductor devices are provided. In one aspect, a method includes providing a first deck comprising a first stack of first sacrificial layers and first isolating layers extending along a first direction. At least a part of the first deck is etched to form a first staircase structure. A second deck adjacent to the first deck along a second direction is provided, the second deck comprising a second stack of second sacrificial layers and second isolating layers extending along the first direction, the second sacrificial layers and the second isolating layers alternating with each other along the second direction. At least a part of the second deck is etched to form a second staircase structure. Contact structures extending through at least one of the first staircase structure or the second staircase structure along the second direction are formed.

### CROSS-REFERENCE TO RELATED APPLICATIONS

This application claims priority to Chinese Patent Application No. 202410161447.0, filed on Feb. 4, 2024, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing vertical structures in three-dimensional (3D) semiconductor devices.

One aspect of the present disclosure features a semiconductor device including a first deck including a first staircase structure extending along a first direction; and a second deck adjacent to the first deck along a second direction perpendicular to the first direction, where the second deck includes a second staircase structure, and where the first staircase structure is adjacent to or has a gap with the second staircase structure on the first direction.

In some implementations, the second deck includes a stack of conductive layers and isolating layers alternating with each other along the second direction, and the stack of conductive layers and isolating layers is adjacent to the first staircase structure along the second direction.

In some implementations, the first direction and the second direction define a first plane, where a first area is a projection of the first staircase structure on the first plane, where a second area is a projection of the second staircase structure on the first plane, and where the first area has the same shape as the second area.

In some implementations, each of the first area and the second area is a V-shaped area.

In some implementations, the first staircase structure includes a first staircase substructure and a second staircase substructure, the first staircase substructure includes first staircase steps descending along the first direction, and the second staircase substructure includes second staircase steps ascending along the first direction.

In some implementations, the first deck includes an array region, a wall region, and a connection region including the first staircase structure, where the wall region is adjacent to the connection region along a third direction perpendicular to the first direction and the second direction, and where the second staircase steps ascending along the first direction are coupled to the array region via the wall region.

In some implementations, the first deck includes a third staircase structure, and the third staircase structure is adjacent to the first staircase structure on the first direction, and where the second deck includes a fourth staircase structure, and the second staircase structure has a gap with the fourth staircase structure on the first direction.

In some implementations, a third area is a projection of the third staircase structure on the first plane, where a fourth area is a projection of the fourth staircase structure on the first plane, and where the third area has the same shape as the fourth area.

In some implementations, each of the first staircase structure and the third staircase structure is in between the second staircase structure and the fourth staircase structure along the first direction.

In some implementations, the semiconductor device includes a contact structure having a first segment in the first deck and a second segment in the second deck, and where each of the first segment and the second segment has a first diameter at the top and a second diameter at the bottom along the second direction, and the first diameter is greater than the second diameter.

Another aspect of the present disclosure features a method including: providing a first deck including a first stack of first sacrificial layers and first isolating layers extending along a first direction, the first sacrificial layers and the first isolating layers alternating with each other along a second direction perpendicular to the first direction; etching at least a part of the first deck to form a first staircase structure; providing a second deck adjacent to the first deck along the second direction, the second deck including a second stack of second sacrificial layers and second isolating layers extending along the first direction, the second sacrificial layers and the second isolating layers alternating with each other along the second direction; etching at least a part of the second deck to form a second staircase structure; and forming contact structures extending through at least one of the first staircase structure or the second staircase structure along the second direction.

In some implementations, the first staircase structure is adjacent to or has a gap with the second staircase structure on the first direction.

In some implementations, the first staircase structure includes a staircase step, and where the method includes depositing a protective layer on a top surface of the staircase step.

In some implementations, the first deck includes a first array region and a first connection region, where the first connection region includes the first staircase structure and is adjacent to the first array region along the first direction, and where the method includes: forming (i) first gate line holes in the first array region and the first connection region, (ii) first channel holes in the first array region and the first connection region, and (iii) first contact holes in the first connection region, where the first gate line holes, the first channel holes, and the first contact holes extend through the first deck along the second direction, and where the first gate line holes, the first channel holes, and the first contact holes are formed during a same first etching process.

In some implementations, the second deck includes a second array region and a second connection region, where the second connection region includes the second staircase structure and is adjacent to the second array region along the first direction, and where the method includes, after providing the second deck: forming (i) second gate line holes in the second array region and the second connection region, (ii) second channel holes in the second array region and the second connection region, and (iii) second contact holes in the second connection region, where the second gate line holes, the second channel holes, and the second contact holes extend through the second deck along the second direction, and where the second gate line holes, the second channel holes, and the second contact holes are formed during a same second etching process.

In some implementations, after forming the second gate line holes, the second channel holes, and the second contact holes, the method includes: removing sacrificial material from the first sacrificial layers and the second sacrificial layers; and depositing conductive material in the first sacrificial layers and the second sacrificial layers to form first conductive layers and second conductive layers, respectively.

In some implementations, forming the contact structures extending through at least one of the first staircase structure or the second staircase structure includes: forming first contact structures and second contact structures, where the first contact structures extend through the first staircase structure and do not extend through the second staircase structure, and where the second contact structures extend through the second staircase structure and do not extend through the first staircase structure.

In some implementations, the first contact structures extend through the second conductive layers and the second isolating layers, and the second contact structures extend through the first conductive layers and the first isolating layers; or the first contact structures extend through an insulating structure included in the second deck, and the second contact structures extend through the first conductive layers and the first isolating layers.

In some implementations, etching at least a part of the first deck to form the first staircase structure includes: etching a first part of the first deck to form the first staircase structure, while a second part of the first deck remains unetched, where the second part of the first deck is adjacent to the first part of the first deck along a third direction perpendicular to the first direction and the second direction, and where the second part of the first deck includes a part of the first stack of first sacrificial layers and first isolating layers; removing sacrificial material from sacrificial layers of the second part of the first deck; and depositing at least one conductive material in the second part of the first deck to form a wall region.

A further aspect of the present disclosure features a system, including: a semiconductor device including: a first deck including a first staircase structure, where the first staircase structure has a first starting point and a first ending point on a first direction, and where the first starting point and the first ending point define a first interval; and a second deck adjacent to the first deck along a second direction perpendicular to the first direction, where the second deck includes a second staircase structure, the second staircase structure has a second starting point and a second ending point on the first direction, and the second starting point and the second ending point define a second interval, and where the first interval is adjacent to or has a gap with the second interval; and a memory controller electrically connected to the semiconductor device, where the memory controller is configured to control the semiconductor device.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates an example 3D semiconductor structure.

FIG. 1B illustrates a top view of an example 3D semiconductor structure, according to some aspects of the present disclosure.

FIG. 1C depicts cross-sectional views of an example 3D semiconductor structure along cut lines AA′ and BB′ shown in FIG. 1B, according to some aspects of the present disclosure.

FIGS. 2A-2C show first example staircase structures for 3D semiconductor structure, according to some aspects of the present disclosure.

FIGS. 3A-3C show second example staircase structures for 3D semiconductor structure, according to some aspects of the present disclosure.

FIGS. 4A-4B show third example staircase structures for 3D semiconductor structure, according to some aspects of the present disclosure.

FIGS. 5A-5O show cross-sectional views of structures of an example semiconductor structure after various stages of a fabrication process, according to some aspects of the present disclosure.

FIG. 6 is a flow chart of an example process of forming a semiconductor structure, according to some aspects of the present disclosure.

FIG. 7 illustrates a block diagram of a system having one or more semiconductor devices, according to one or more implementations of the present disclosure.

Like reference numbers and designations in the various drawings indicate like elements. It is also to be understood that the various exemplary implementations shown in the figures are merely illustrative representations and are not necessarily drawn to scale.

### DETAILED DESCRIPTION

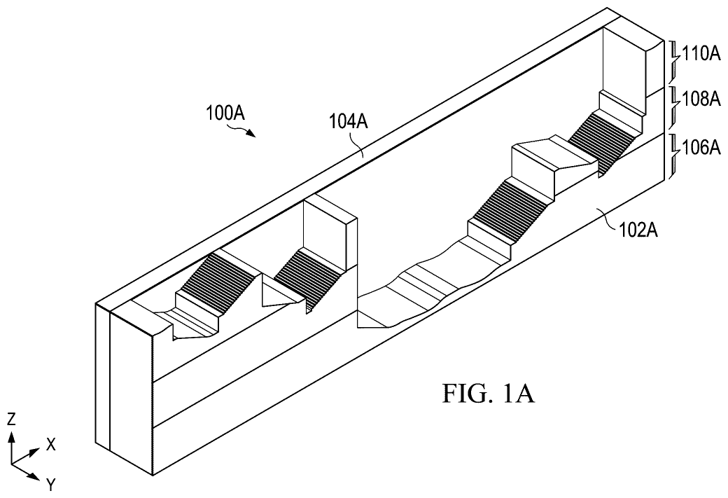

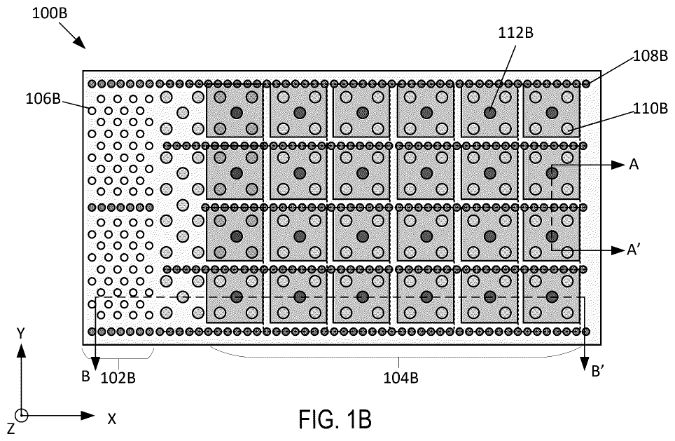

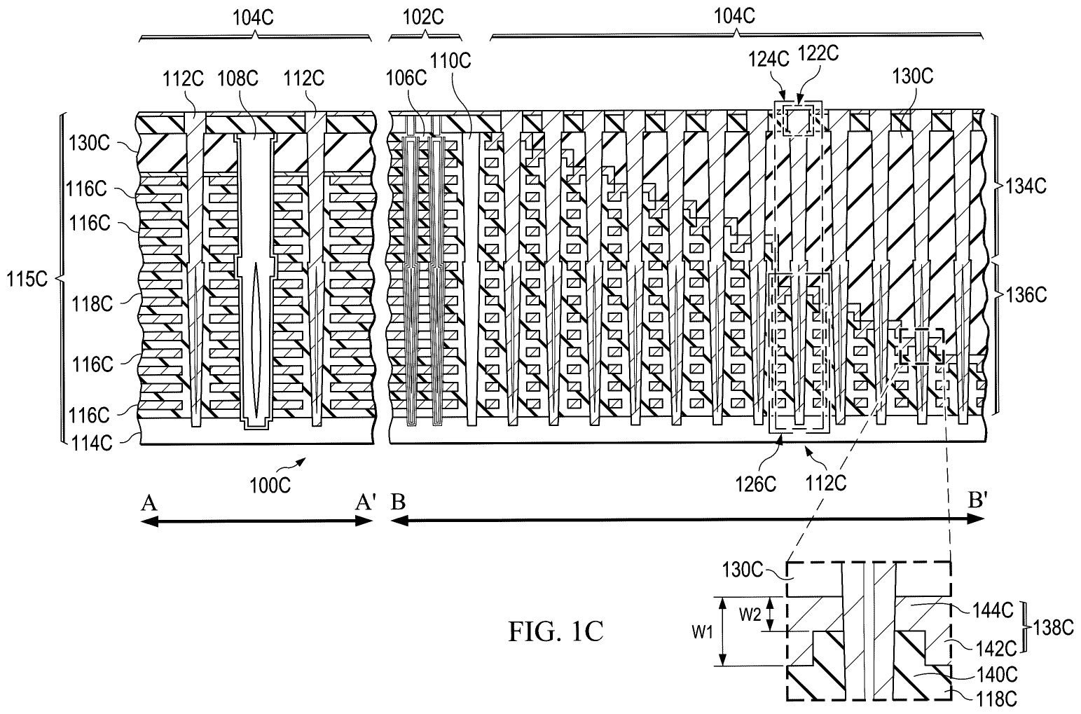

FIG. 1A illustrates an example 3D semiconductor structure 100A. As illustrated, the example 3D semiconductor structure 100A includes three decks 106A, 108A, and 110A sequentially stacked together vertically (i.e., along the Z direction). Along the Y direction, the example 3D semiconductor structure 100A includes a staircase structure 102A and a wall region 104A. In some examples, the staircase structure 102A is formed after all the three decks three decks 106A, 108A, and 110A are formed. FIGS. 1B-1C depict other example multi-deck 3D semiconductor structures that are formed using a different process than that of the example 3D semiconductor structure 100A. As described with more details below, in the example 3D semiconductor structures described with respect to FIGS. 1B-1C, staircase structure of each deck is formed during the respective forming process of the corresponding deck.

FIG. 1B illustrates an example 3D semiconductor structure 100B and FIG. 1C illustrates an example 3D semiconductor structure 100C corresponding to the example 3D semiconductor structure 100B. While the example 3D semiconductor structure 100B and the example 3D semiconductor structure 100C are similar 3D semiconductor structures, the example 3D semiconductors structure 100C can include additional, fewer, or different structures than the example 3D semiconductor structure 100B. FIG. 1B is a top view of the example 3D semiconductor structure 100B, and FIG. 1C depicts cross-sectional views of the example 3D semiconductor structure 100C along cut lines AA′ and BB′ shown in FIG. 1B. The 3D semiconductor structure 100B and/or the 3D semiconductor structure 100C can be used to form a memory device, e.g., a 3D NAND memory device.

It is noted that X, Y, and Z axes (also referred to as X, Y, and Z directions) are included in FIGS. 1A-1B to further illustrate the spatial relationship of various components in a semiconductor structure. A semiconductor layer of the semiconductor structure includes two lateral surfaces extending laterally in the X-Y plane: a top surface on the front side of a wafer on which a component of the semiconductor structure can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor structure is determined relative to the semiconductor layer of the semiconductor structure in the Z direction (the vertical direction perpendicular to the X-Y plane, e.g., the thickness direction of the semiconductor layer) when the semiconductor layer is positioned in the lowest plane of the semiconductor structure in the Z direction. The same notion for describing the spatial relationships is applied throughout the present disclosure.

FIG. 1B illustrates a top view of the semiconductor structure 100B, according to some aspects of the present disclosure. The semiconductor structure 100B includes an array region 102B and a connection region 104B. The connection region 104B, which can also be referred to as a staircase region, is adjacent to the array region 102B in a first horizontal direction (e.g., the X direction). The array region 102B includes an array of channel structures 106B. Each channel structure 106B can be used to form a string of memory cells coupled in serial along a vertical direction (e.g., the Z direction) perpendicular to the X-Y plane. The connection region 104B includes channel structures 110B and contact structures 112B. The channel structures 110B in the connection region 104B can also be referred to as dummy channel structures. The semiconductor structure 100B includes gate line slit structures 108B extending through both of the array region 102B and the connection region 104B along the X direction. In some implementations, a gate line slit structure in the connection region 104B has a greater width in a second horizontal direction (e.g., the Y direction) than a gate line slit structure in the array region 102B. In some implementations, a gate line slit structure in the connection region 104B has a same width as a gate line slit structure in the array region 102B. In some implementations, a gate line slit structure in the connection region 104B has a smaller width than a gate line slit structure in the array region 102B. FIG. 1B further shows cut lines AA′ and BB′ for generating cross-sectional views in FIG. 1C.

FIG. 1C illustrates cross-sectional views of the semiconductor structure 100C along lines AA′ and BB′, according to some aspects of the present disclosure. As shown in FIG. 1C, the semiconductor structure 100C includes a semiconductor layer 114C and a stack 115C of conductive layers 116C and isolating layers 118C provided over the semiconductor layer 114C. The semiconductor layer 114C can be any suitable semiconductor layer having any suitable semiconductor materials, such as monocrystalline, polycrystalline or single crystalline semiconductors. For example, the semiconductor layer 114C can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof.

The stack 115C can extend in the X-Y plane in parallel with a top surface of the semiconductor layer 114C. The conductive layers 116C and the isolating layers 118C can alternate in the vertical direction (e.g., the Z direction) perpendicular to the X-Y plane. The conductive layers 116C and the isolating layers 118C can extend from the array region 102C into the connection region 104C and be arranged in a staircase-like structure in the connection region 104C. The conductive layers 116C can be the same or different from each other in thickness, for example, ranging from 10-500 nanometers (nm), e.g., about 35 nm. The isolating layers 118C can also be the same or different from each other in thickness, for example, ranging from 10-500 nm, e.g., about 25 nm. The conductive layers 116C can include any suitable conducting material, such as tungsten (W), cobalt (Co), copper (Cu), aluminum (Al), titanium nitride (TiN), polycrystalline silicon (polysilicon), doped silicon, silicide, or any combination thereof. The isolating layers 118C can include a dielectric material, such as silicon oxide, silicon nitride, silicon oxynitride, or any combination thereof. In some implementations, the isolating layers 118C can also include high-k dielectric materials, such as hafnium oxide, zirconium oxide, aluminum oxide, tantalum oxide, lanthanum oxide, or any combination thereof. It should be noted that the number of the conductive layers 116C and the isolating layers 118C shown in FIG. 1C is for illustration only and that any suitable number of conductive layers and isolating layers can be included in the semiconductor structure 100C.

As shown in FIG. 1C, each contact structure 112C has a head 122C and a body 124C. The contact structure 112C can extend through the connection region 104C along the vertical direction (e.g., the Z direction). The head 122C of the contact structure 112C can extend through a spacer layer (not shown in FIG. 1C) provided over the stack 115C, and a bottom end of the body 124C can extend through the semiconductor layer 114C. Due to the staircase-like structure formed by the stack 115C in the connection region 104C, the body 124C can extend through a portion of the stack 115C, which is included in a step of the staircase-like structure (e.g., step 126C as shown in FIG. 1C).

The staircase-like structure formed by the conductive layers 116C and isolating layers 118C allow the contact structures 112C to connect the conductive layers 116C to external components. Each conductive layer 116C can be coupled to a corresponding contact structure and can be isolated from one or more other contact structures. In some implementations, each contact structure 112C can be coupled to a respective conductive layer. The contact structure 112C can extend through a set of conductive layers of the stack 115C. The contact structure 112C can be in contact with one conductive layer that is closest to the head 122C of the contact structure 112C among the set of conductive layers. For example, as shown in FIG. 1C, each contact structure 112C can extend through conductive layers in a staircase step (e.g., step 126C) and can be coupled to a topmost conductive layer in that staircase step. One or more contact spacers can be located between the contact structure 112C and one or more other conductive layers of the set of conductive layers and can isolate the contact structure 112C from these conductive layers. Each contact spacer can include a dielectric material. In some other implementations (not shown in FIG. 1C), each contact structure 112C can be coupled to multiple conductive layers 116C. In some implementations, the contact structure 112C can be coupled out either through the head 122C to a conductive contact on a top surface of the semiconductor structure 100C, or through the bottom end of the body 124C to a conductive contact on a bottom surface of the semiconductor structure 100C, or both.

The connection region 104C further includes an insulating structure 130C. The insulating structure 130C can include a dielectric material such as silicon oxide.

As shown in FIG. 1C, the semiconductor structure 100C includes two decks 134C and 136C sequentially stacked together vertically (i.e., along the Z direction). Each deck includes a respective subset of conductive layers and isolating layers of the stack 115C. The body 124C of each contact structure 112C includes two segments each formed in a corresponding deck. The two segments of the body 124C are sequentially connected together along the vertical direction. Each segment of the body 124C can be shaped like a pillar or a truncated cone and can have a diameter gradually reduced along the vertical direction from top to bottom. For example, each segment can have a first diameter at the top and a second diameter at the bottom along the Z direction, and the first diameter is greater than the second diameter.

At an intersection of two adjacent decks, a top of a lower segment of the body 124C can have a larger diameter than a bottom of an upper segment of the body 124C. For example, for each contact structure 112C, a top of a segment of the contact structure 112C in deck 136C is thicker than a bottom of another segment of the contact structure 112C in deck 134C. It should be noted that the two decks shown in FIG. 1C are for illustration purposes only and that any suitable number (including one) of decks can be included in the semiconductor structure 100C.

Contact structure 112C extends through the stack along the Z-direction. In some examples, contact structure 112C may include conductive materials including, but not limited to, W, Co, Cu, Al, polysilicon, doped silicon, silicides, or any combination thereof. In some examples, contact structure 112C and conductive layer 116C may be formed by the same material.

Conductive layers 116C may include a topmost conductive layer, e.g., a first conductive layer 138C, and other conductive layers under the topmost conductive layer, e.g., a second conductive layer 148C. First conductive layer 138C is in contact with contact structure 112C. In some implementations, a spacer layer 140C is formed between contact structure 112C and second conductive layer 148C. It is understood that the “topmost conductive layer” used here refers to the topmost conductive layer of each staircase-like structure shown in FIG. 1C, not the whole memory structure. In other words, the topmost conductive layer in different staircase-like structures may be different conductive layers in the whole memory structure. As shown in FIG. 1C, spacer layer 140C extends along the Z-direction and insulates contact structure 112C and second conductive layer 148C.

First conductive layer 138C includes a first portion 142C having a first thickness W1 and a second portion 144C having a second thickness W2 less than the first thickness in contact with contact structure 112C. First portion 142C of first conductive layer 138C is disposed above an isolating layer 118C, and second portion 144C of first conductive layer 138C is disposed above spacer layer 140C.

In other words, first portion 142C of first conductive layer 138C is in contact with second portion 144C of first conductive layer 138C, and second portion 144C extrudes out first portion 142C along the X direction perpendicular to the Z direction. In some implementations, a top surface of first portion 142C of first conductive layer 138C is coplanar with a top surface of second portion 144C of first conductive layer 138C. In some implementations, second conductive layer 148C has a third thickness less than the first thickness of first portion 142C.

The channel structures 106C and the dummy channel structures 110C extend through the stack 115C along the vertical direction (e.g., the Z direction). Each channel structure 106C can have one or more segments. Each of the one or more segments is in a corresponding deck of the semiconductor structure 100C and is shaped like a pillar or a truncated cone. The channel structure 106C can include a memory film and a semiconductor channel. In some examples, the memory film includes a blocking layer, a charge trapping layer and a tunneling layer. In some examples, a material for the blocking layer may include silicon oxide, silicon nitride, silicon oxynitride, and a high-k dielectric material such as aluminum oxide or hafnium oxide; a material for the charge trapping layer may include polysilicon, silicon nitride, or silicon oxynitride; and a material for the tunneling layer may include silicon oxide, silicon nitride, silicon oxynitride, a high-k dielectric material such as aluminum oxide or hafnium oxide. In an example, the materials of the blocking layer, the charge trapping layer, the tunneling layer and the semiconductor channel may include silicon oxide, silicon nitride, silicon oxide and polysilicon respectively. Each dummy channel structure 110C can include a structure and materials similar to the channel structure 106C. In some implementations, the dummy channel structure 110 can be used to support the stack 115C within the connection region 104C.

FIG. 1C shows a cross-sectional view of the gate line slit structures 108C along line AA′. The gate line slit structures 108C extend through the stack 115C along the Z direction. The gate line slit structures 108C can divide the semiconductor structure 100C into multiple blocks. Each gate line slit structure 108C can include a gate line trench filled with a trench filler material (e.g., polysilicon). The gate line trench can be formed in the following process. A series of gate line holes can be formed in the semiconductor structure 100C along the X direction. Each of the gate line holes extends through the semiconductor structure 100C along the Z direction. Each of the series of gate line holes can then be expanded (e.g., by etching). Two adjacent gate line holes can connect to each other after expansion, which turns the series of gate line holes into the gate line trench.

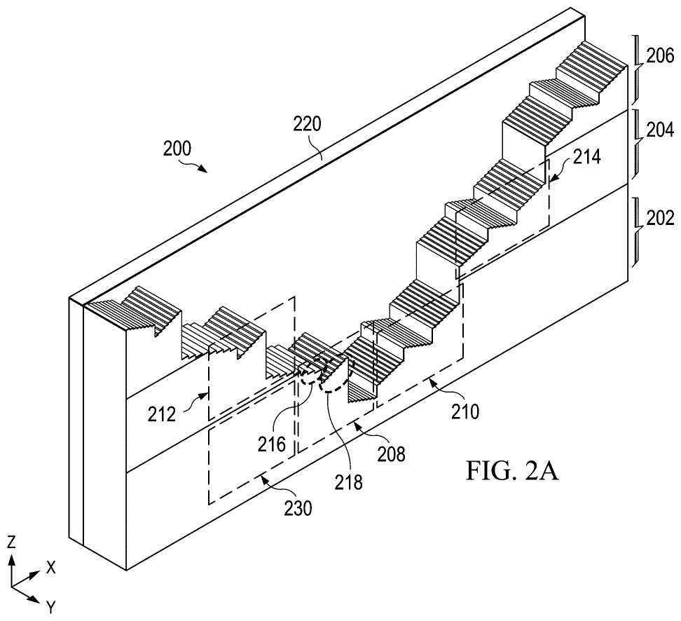

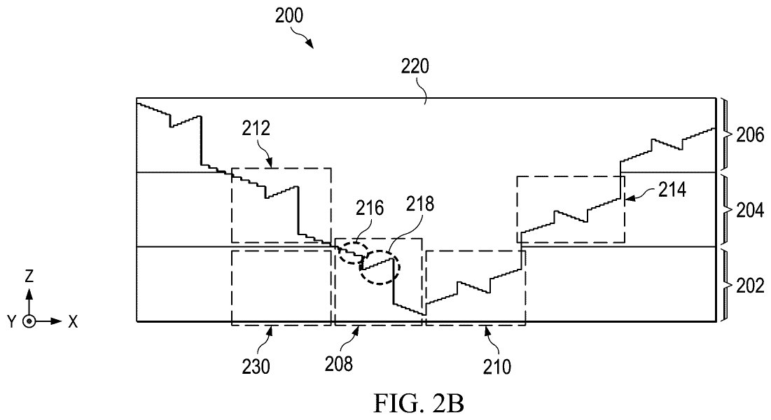

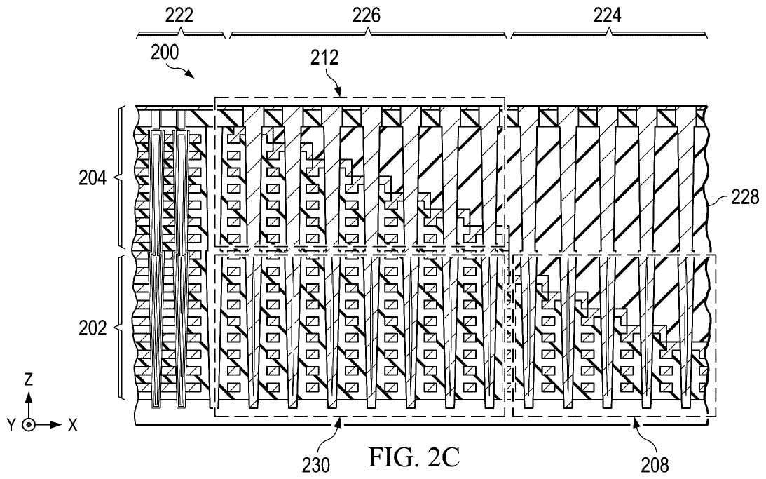

FIGS. 2-4 show example staircase structures for 3D semiconductor structures that are similar to, or the same as, the 3D semiconductor structure 100A/3D semiconductor structure 100B of FIGS. 1A-1B. The example staircase structures described with respect to FIGS. 2-4 are not limited to the 3D semiconductor structure 100A/3D semiconductor structure 100B of FIGS. 1A-1B. For example, any of the example staircase structures described with respect to FIGS. 2-4 can be formed in a 3D semiconductor structure whose gate line trench is not formed based on gate line holes.

FIGS. 2A-2C show first example staircase structures for 3D semiconductor structure 200 (which can be operationally and/or structurally similar to the 3D semiconductor structure 100A/3D semiconductor structure 100B), according to some aspects of the present disclosure. As depicted in FIGS. 2A-2B, the 3D semiconductor structure 200 includes three decks sequentially stacked together vertically (i.e., along the Z direction). Each of the three decks includes a respective connection region. For example, the deck at the bottom along the Z direction includes the connection region 202, the deck at the middle along the Z direction includes the connection region 204, and the deck at the top along the Z direction includes the connection region 206. Each of the three connection regions includes respective staircase structures extending along a first horizontal direction (e.g., the X direction). For example, the connection region 202 includes staircase structures 208 and 210, and the connection region 204 includes staircase structures 212 and 214.

In some implementations, for two decks adjacent to each other along the vertical direction, where the first deck includes a first staircase structure and the second deck includes a second staircase structure, the first staircase structure is adjacent to or has a gap with the second staircase structure on the first horizontal direction. A projection of the first staircase structure on the first horizontal direction can be a line segment which has a first starting point X1 and a first ending point X2 on the first horizontal direction. The first starting point X1 and the first ending point X2 define a first interval [X1, X2]. Similarly, a projection of the second staircase structure on the first horizontal direction can be another line segment which has a second starting point Y1 and a second ending point Y2 on the first horizontal direction. The second starting point Y1 and the second ending point Y2 define a second interval [Y1, Y2]. In some cases, the first staircase structure is adjacent to the second staircase structure on the first horizontal direction, so the first interval [X1, X2] is adjacent to the second interval [Y1, Y2] (i.e., X2=Y1 or X1=Y2). In other cases, the first staircase structure has a gap with the second staircase structure on the first horizontal direction, so the first interval [X1, X2] does not overlap with the second interval [Y1, Y2]. The same notion for describing the spatial relationships is applied throughout the present disclosure.

For example, as depicted in FIGS. 2A-2B, the staircase structure 208 is adjacent to the staircase structure 212 on the X direction. In some implementations, the staircase structure 208 can have a gap with the staircase structure 212 on the X direction.

In some cases, the first deck includes a third staircase structure, and the third staircase structure is adjacent to the first staircase structure on the first horizontal direction. The second deck includes a fourth staircase structure, and the second staircase structure has a gap with the fourth staircase structure on the first horizontal direction. For example, as depicted in FIGS. 2A-2B, the first deck includes the staircase structure 210, and the staircase structure 210 is adjacent to the staircase structure 208 on the X direction. The second deck includes the staircase structure 214, and the staircase structure 212 has a gap with the staircase structure 214 on the X direction.

In some examples, the first horizontal direction and the vertical direction define a first plane (e.g., the X-Z plane). A first area is a projection of the first staircase structure on the first plane. A second area is a projection of the second staircase structure on the first plane. In some examples, the first area has the same shape as the second area. In one example, as depicted in FIG. 2B, assuming that the first area is a projection of the staircase structure 208 on the X-Z plane, and that a second area is a projection of the staircase structure 212 on the X-Z plane, the first area has the same shape as the second area. In another example, as depicted in FIG. 2B, assuming that the third area is a projection of the staircase structure 210 on the X-Z plane, and that a fourth area is a projection of the staircase structure 214 on the X-Z plane, the third area has the same shape as the fourth area.

In some examples, a staircase structure includes a first staircase substructure and a second staircase substructure, the first staircase substructure includes first staircase steps descending along the first horizontal direction, and the second staircase substructure includes second staircase steps ascending along the first horizontal direction. For example, as depicted in FIGS. 2A-2B, the staircase structure 208 includes a first staircase substructure 216 and a second staircase substructure 218, the first staircase substructure 216 includes first staircase steps descending along the X direction, and the second staircase substructure 218 includes second staircase steps ascending along the X direction.

In some examples, in addition to the connection region, a deck includes an array region (now shown in FIGS. 2A-2B) and a wall region. The wall region is adjacent to the connection region along a second horizontal direction (e.g., the Y direction) perpendicular to the first horizontal direction and the vertical direction. The second staircase steps ascending along the first horizontal direction are coupled to the array region via the wall region. For example, in addition to the connection region 202, the deck includes an array region 222 (as shown in FIG. 2C) and a wall region 220. The wall region 220 is adjacent to the connection region 202 along the Y direction. The second staircase steps of the second staircase substructure 218 ascending along the X direction are coupled to the array region via the wall region 220. In some cases, the wall region includes a plurality of alternating conductive layers and isolating layers. A conductive layer of the wall region can be coupled to (i) a topmost conductive layer of a staircase step of the second staircase steps and (ii) a word line that coupled to a conductive layer (e.g., the conductive layers 116) of the array region. By doing so for each staircase step of the second staircase steps, the second staircase steps ascending along the first horizontal direction can be coupled to the array region via the wall region.

As depicted in FIG. 2C, the connection region 202 includes a stack 230 of conductive layers and isolating layers alternating with each other along the Z direction, and the stack 230 of conductive layers and isolating layers is adjacent to the staircase structure 212 along the Z direction. While some components in FIG. 2C (e.g., 208, 212, and 230) are shown with the same labels as these components in FIGS. 2A-2B, the illustrations of these components in FIG. 2C may omit some structures that are shown in FIGS. 2A-2B. The contact structures 224 extend through the staircase structure 208 and the insulating structure 228, but do not extend through the staircase structure 212. On the other hand, contact structures 226 extend through the staircase structure 212 and the stack 230 of conductive layers and isolating layers, but do not extend through the staircase structure 208.

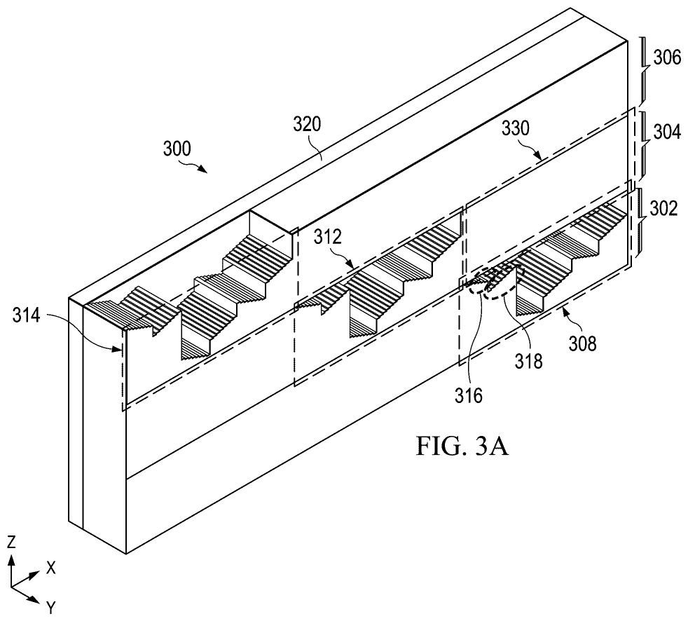

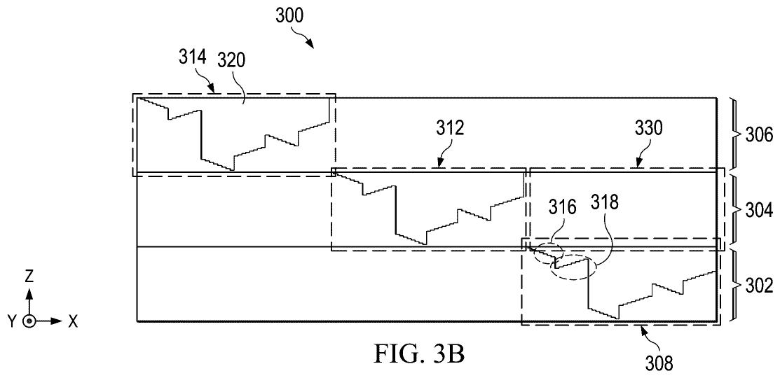

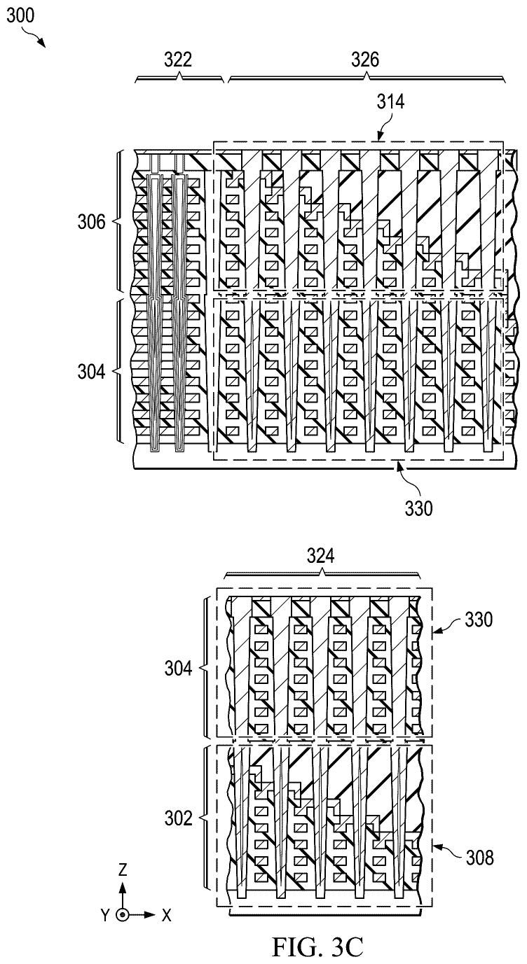

FIGS. 3A-3C show second example staircase structures for 3D semiconductor structure 300 (which can be operationally and/or structurally similar to the 3D semiconductor structure 100A/3D semiconductor structure 100B), according to some aspects of the present disclosure. As depicted in FIGS. 3A-3B, the 3D semiconductor structure 300 includes three decks sequentially stacked together vertically (i.e., along the Z direction). Each of the three decks includes a respective connection region. For example, the deck at the bottom along the Z direction includes the connection region 302, the deck at the middle along the Z direction includes the connection region 304, and the deck at the top along the Z direction includes the connection region 306. Each of the three connection regions includes a respective staircase structure extending along a first horizontal direction (e.g., the X direction). For example, the connection region 302 includes staircase structures 308, the connection region 304 includes staircase structures 312, and the connection region 306 includes staircase structures 314.

In some implementations, for two decks adjacent to each other along the vertical direction, where the first deck includes a first staircase structure and the second deck includes a second staircase structure, the first staircase structure is adjacent to or has a gap with the second staircase structure on the first horizontal direction. For example, as depicted in FIGS. 3A-3B, the staircase structure 308 is adjacent to the staircase structure 312 on the X direction. In some implementations, the staircase structure 308 can have a gap with the staircase structure 312 on the X direction.

In some examples, the first horizontal direction and the vertical direction define a first plane (e.g., the X-Z plane). A first area is a projection of the first staircase structure on the first plane. A second area is a projection of the second staircase structure on the first plane. In some examples, the first area has the same shape as the second area. For example, as depicted in FIG. 3B, assuming that the first area is a projection of the staircase structure 308 on the X-Z plane, and that a second area is a projection of the staircase structure 312 on the X-Z plane, the first area has the same shape as the second area.

In some examples, a staircase structure includes a first staircase substructure and a second staircase substructure, the first staircase substructure includes first staircase steps descending along the first horizontal direction, and the second staircase substructure includes second staircase steps ascending along the first horizontal direction. For example, as depicted in FIGS. 3A-3B, the staircase structure 308 includes a first staircase substructure 316 and a second staircase substructure 318, the first staircase substructure 316 includes first staircase steps descending along the X direction, and the second staircase substructure 318 includes second staircase steps ascending along the X direction.

In some examples, in addition to the connection region, a deck includes an array region (now shown in FIGS. 3A-3B) and a wall region. The wall region is adjacent to the connection region along a second horizontal direction (e.g., the Y direction) perpendicular to the first horizontal direction and the vertical direction. The second staircase steps ascending along the first horizontal direction are coupled to the array region via the wall region. For example, in addition to the connection region 302, the deck includes an array region 322 (as shown in FIG. 3C) and a wall region 320, where the wall region 320 is adjacent to the connection region 302 along the Y direction, and where the second staircase steps of the second staircase substructure 318 ascending along the X direction are coupled to the array region via the wall region 320. The wall region 320 can be operationally and/or structurally similar to the wall region 220, and the details are omitted here for brevity.

As depicted by FIG. 3C, the connection region 304 includes a stack 330 of conductive layers and isolating layers alternating with each other along the Z direction. While some components in FIG. 3C (e.g., 308, 314, and 330) are shown with the same labels as these components in FIGS. 3A-3B, the illustrations of these components in FIG. 3C may omit some structures that are shown in FIGS. 3A-3B. The stack 330 of conductive layers and isolating layers is adjacent to the staircase structure 314 and the staircase structure 308 along the Z direction. The contact structures 324 extend through the staircase structure 308 and the stack 330 of conductive layers and isolating layers, but do not extend through the staircase structure 314. On the other hand, contact structures 326 extend through the staircase structure 314 and the stack 330 of conductive layers and isolating layers, but do not extend through the staircase structure 308.

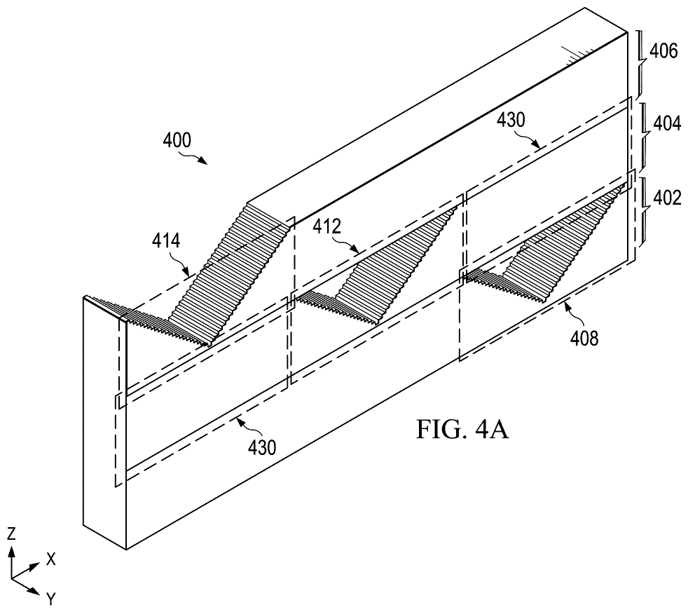

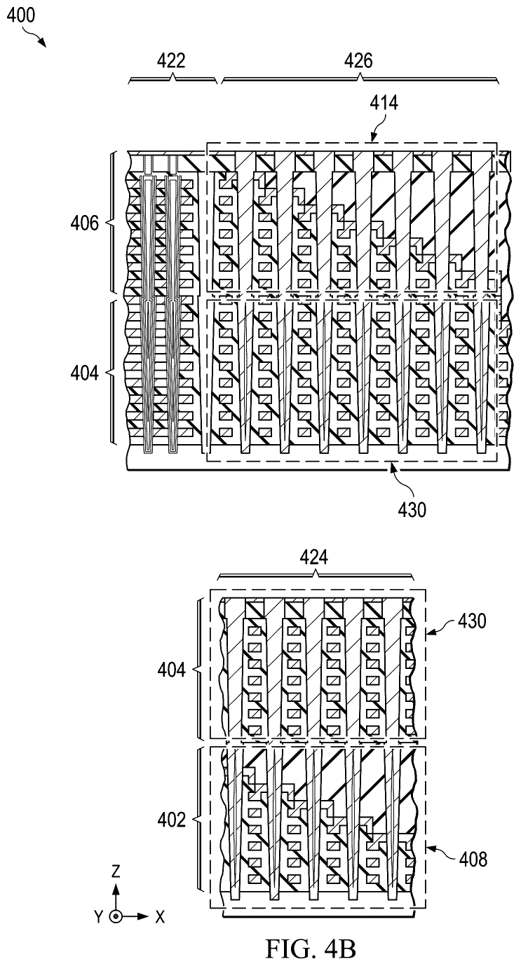

FIGS. 4A-4B show third example staircase structures for 3D semiconductor structure 400 (which can be operationally and/or structurally similar to the 3D semiconductor structure 100A/3D semiconductor structure 100B), according to some aspects of the present disclosure. As depicted in FIG. 4A, the 3D semiconductor structure 400 includes three decks sequentially stacked together vertically (i.e., along the Z direction). Each of the three decks includes a respective connection region. For example, the deck at the bottom along the Z direction includes the connection region 402, the deck at the middle along the Z direction includes the connection region 404, and the deck at the top along the Z direction includes the connection region 406. Each of the three connection regions includes a respective staircase structure extending along a first horizontal direction (e.g., the X direction). For example, the connection region 402 includes staircase structures 408, the connection region 404 includes staircase structures 412, and the connection region 406 includes staircase structures 414.

In some implementations, for two decks adjacent to each other along the vertical direction, where the first deck includes a first staircase structure and the second deck includes a second staircase structure, the first staircase structure is adjacent to or has a gap with the second staircase structure on the first horizontal direction. For example, as depicted in FIG. 4A, the staircase structure 408 is adjacent to the staircase structure 412 on the X direction. In some implementations, the staircase structure 408 can have a gap with the staircase structure 412 on the X direction.

In some examples, the first horizontal direction and the vertical direction define a first plane (e.g., the X-Z plane). A first area is a projection of the first staircase structure on the first plane. A second area is a projection of the second staircase structure on the first plane. In some examples, the first area has the same shape as the second area. For example, as depicted in FIG. 4A, assuming that the first area is a projection of the staircase structure 408 on the X-Z plane, and that a second area is a projection of the staircase structure 412 on the X-Z plane, the first area has the same shape as the second area. In some cases, each of the first area and the second area is a V-shaped area.

In some examples, in addition to the connection region, a deck includes an array region (not shown in FIG. 4A). For example, in addition to the connection region 402, the deck includes an array region 422 (as shown in FIG. 4B). As depicted in FIG. 4B, the connection region 404 includes a stack 430 of conductive layers and isolating layers alternating with each other along the Z direction. While some components in FIG. 4B (e.g., 408, 414, and 430) are shown with the same labels as these components in FIG. 4A, the illustrations of these components in FIG. 4B may omit some structures that are shown in FIG. 4A. The stack 430 of conductive layers and isolating layers is adjacent to the staircase structure 414 and the staircase structure 408 along the Z direction. The contact structures 424 extend through the staircase structure 408 and the stack 430 of conductive layers and isolating layers, but do not extend through the staircase structure 414. On the other hand, contact structures 426 extend through the staircase structure 414 and the stack 430 of conductive layers and isolating layers, but do not extend through the staircase structure 408.

Implementations of the present disclosure can provide one or more of the following technical advantages and/or benefits. For example, in some examples (e.g., the second example staircase structures described with respect to FIGS. 3A-3C and the third example staircase structures described with respect to FIGS. 4A-4B), the total space occupied by the staircase structures can be smaller than other staircase structures (e.g., the first example staircase structures described with respect to FIGS. 2A-2C). Accordingly, less portion of stack of sacrificial layers and insulating layers needs to be removed to form the staircase structures, and the saved portion of the stack can provide additional support to the overall semiconductor structure. Therefore, the stability of the overall semiconductor structure can be enhanced. In some examples, the shape of a staircase structure in a deck can be the same as the shape of another staircase structure in another deck. Therefore, similar, or the same, staircase formation process can be used to form staircase structures on different decks. This can simplify the fabrication process of semiconductor structures, and thus can reduce the fabrications cost.

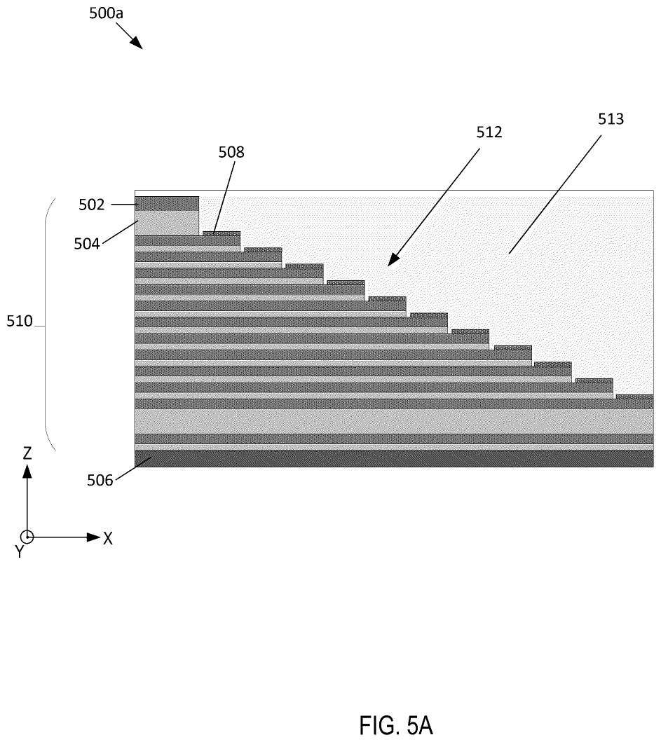

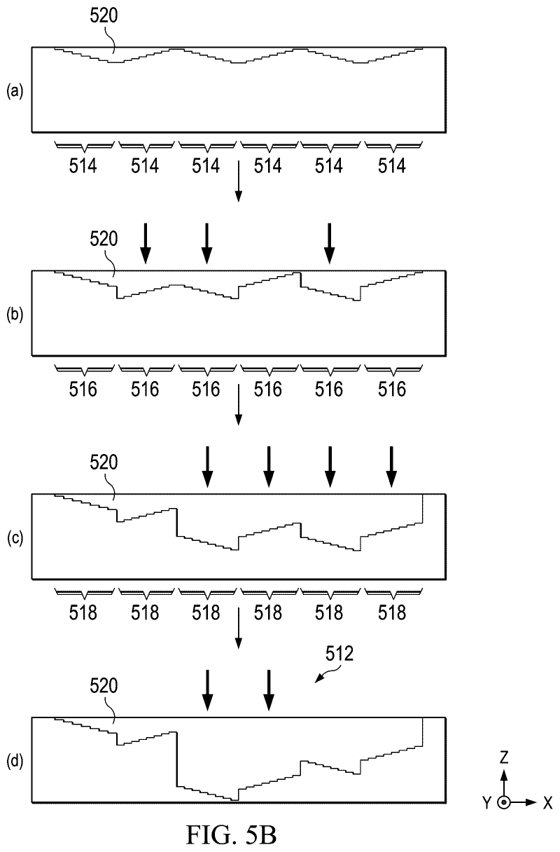

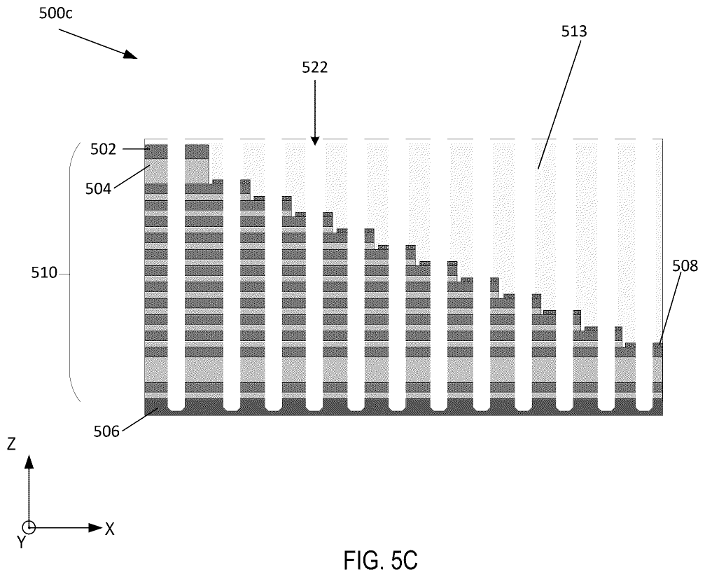

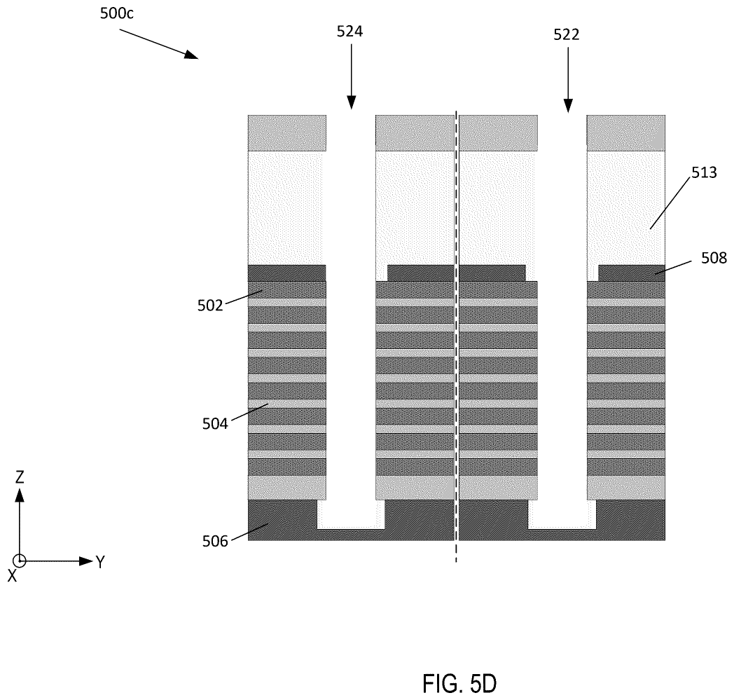

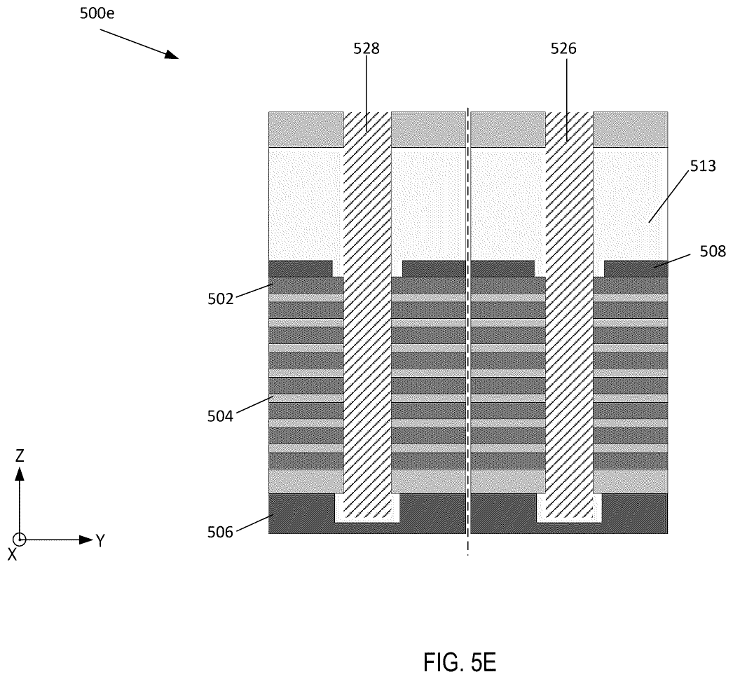

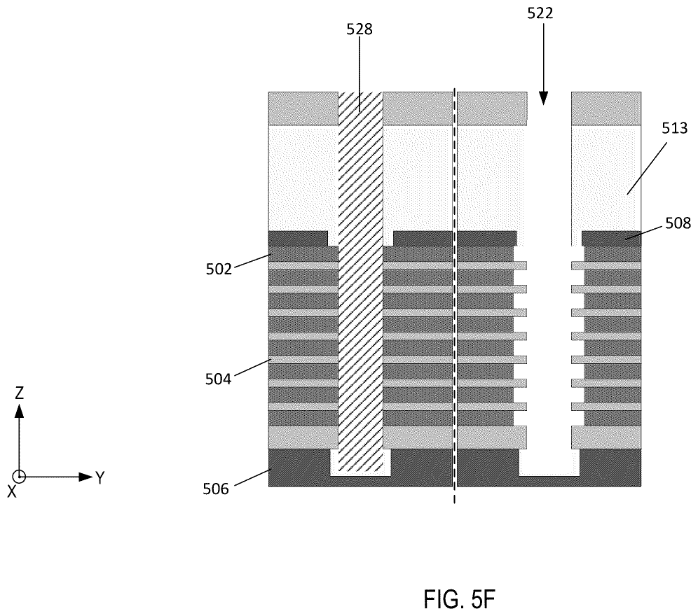

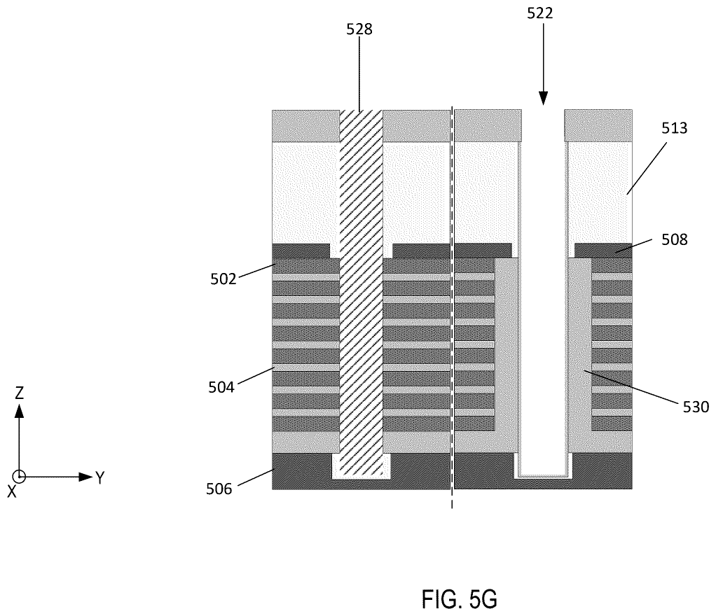

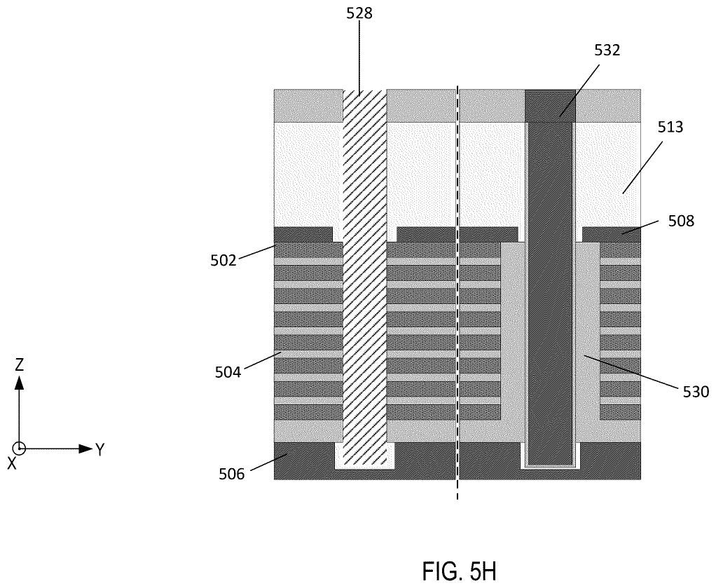

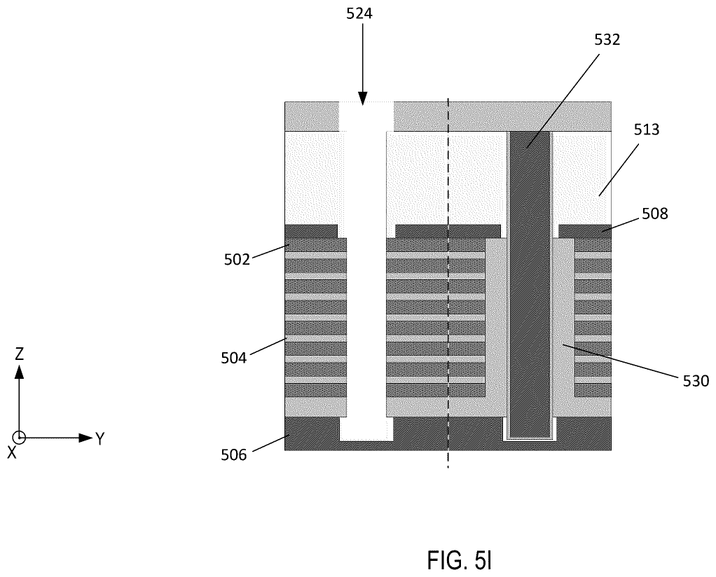

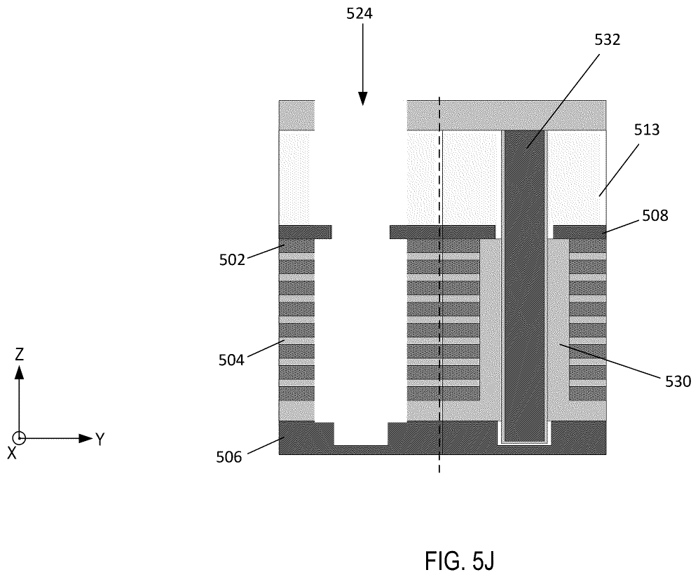

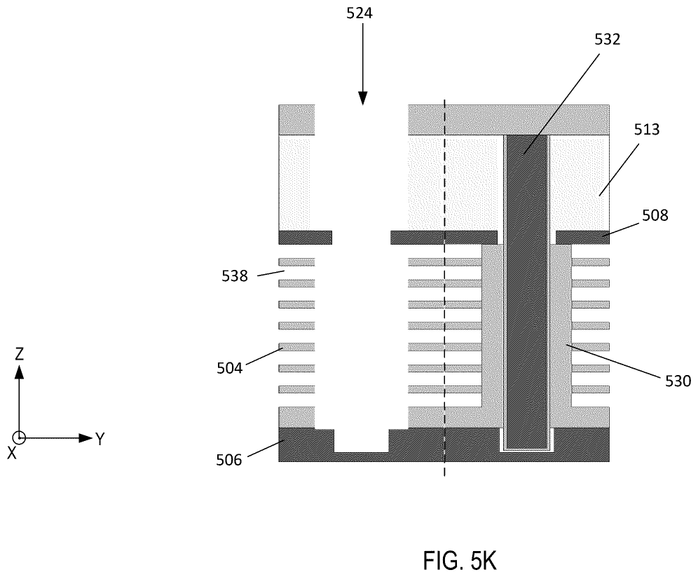

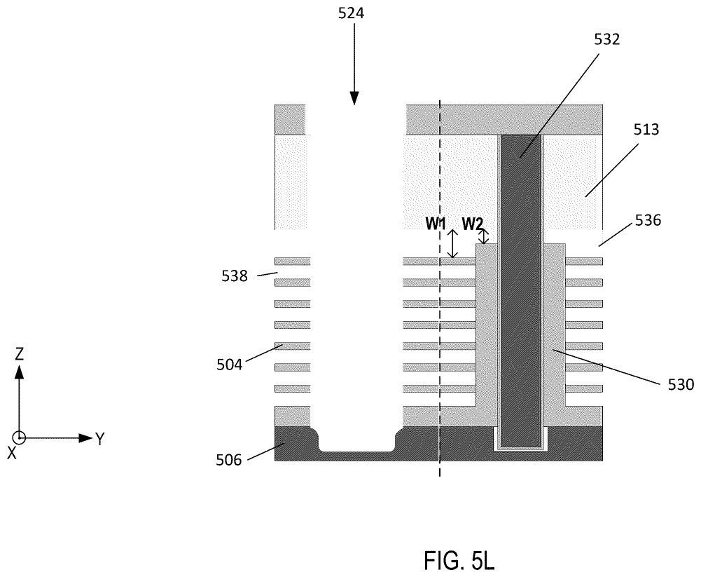

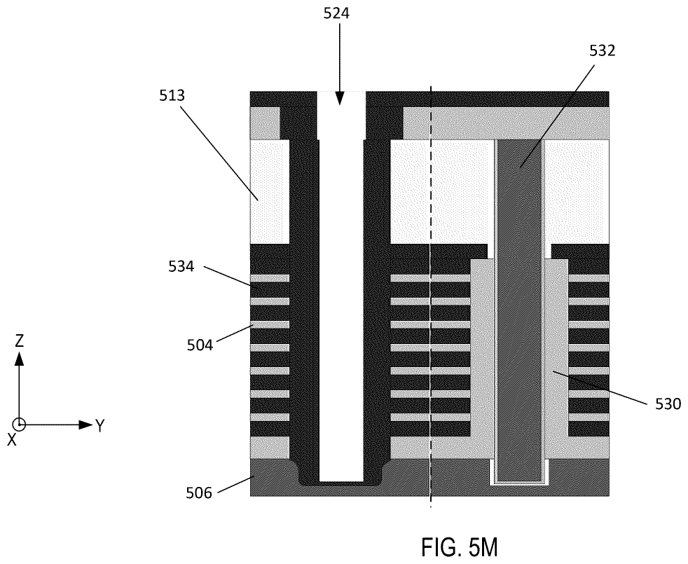

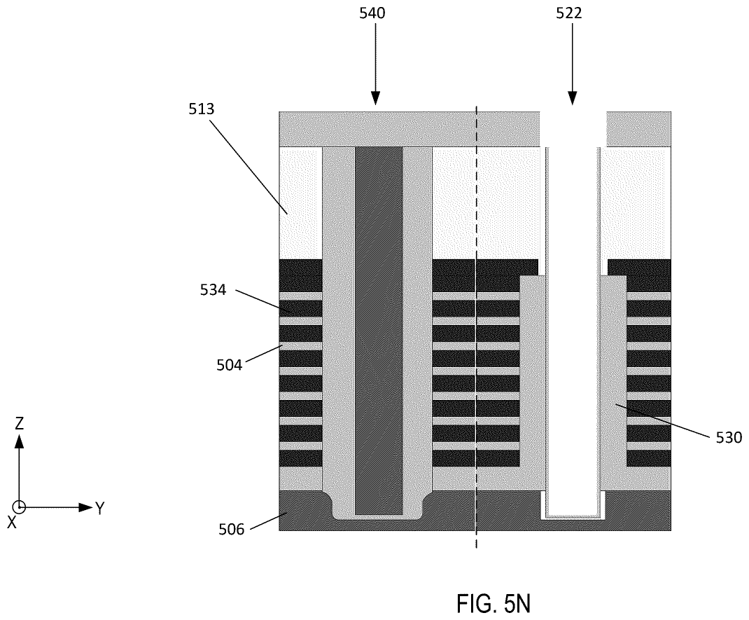

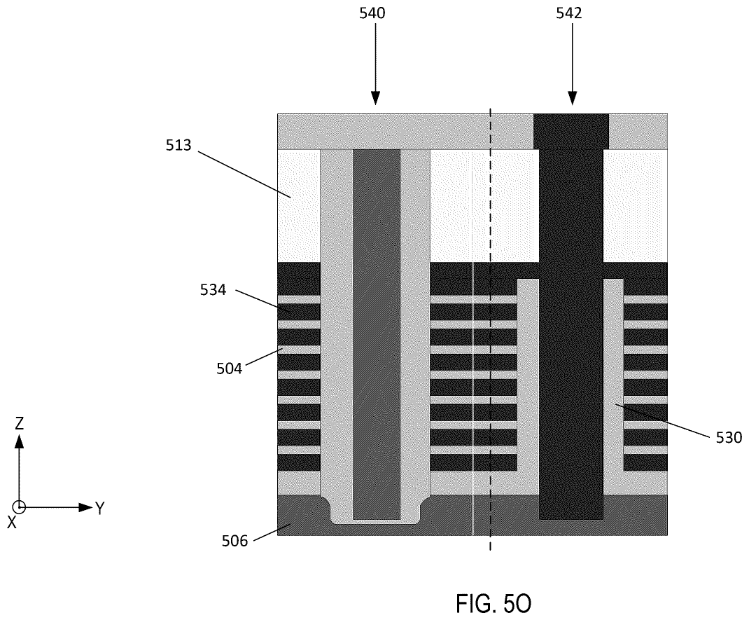

FIGS. 5A-5O show cross-sectional views of structures of an example semiconductor structure after various stages of a fabrication process, according to some aspects of the present disclosure. The semiconductor structure can be similar to, or the same as, the semiconductor structure 100A/3D semiconductor structure 100B of FIGS. 1A-1B (or a part of the semiconductor structure 100A/3D semiconductor structure 100B), the semiconductor structure 200 of FIGS. 2A-2C (or a part of the semiconductor structure 200), the semiconductor structure 300 of FIGS. 3A-3C (or a part of the semiconductor structure 300), or the semiconductor structure 400 of FIGS. 4A-4B (or a part of the semiconductor structure 400).

FIG. 5A shows a structure 500a after a first stage of forming the semiconductor structure. The first stage includes, for example, providing a first deck including a first stack 510 of first sacrificial layers 502 and first isolating layers 504 (e.g., corresponding to the isolating layers 118 of FIG. 1C) extending along a first horizontal direction (e.g., the X direction) and a second horizontal direction (e.g., the Y direction). The first sacrificial layers 502 and the first isolating layers 504 alternate with each other along a vertical direction (e.g., the Z direction) perpendicular to the first horizontal direction and the second horizontal direction. The first sacrificial layer 502 can include a sacrificial material. The sacrificial material can include an insulating material (e.g., silicon dioxide, silicon nitride, or carbon), a semiconducting material (e.g., silicon or gallium arsenide), or others.

In some cases, providing the first deck includes providing a semiconductor layer 506 and depositing the first stack 510 of first sacrificial layers 502 and first isolating layers 504 over the semiconductor layer 506. In some implementations, at least a part of the first deck can be etched to form a first staircase structure 512.

In some implementations, the formation of a staircase structure can include multiple etching operations. FIG. 5B shows an example process of forming the first staircase structure 512. As depicted, at step (a), a first etching operation can be performed on the topmost layer of a stack of sacrificial layers and isolating layers (e.g., the first stack 510), where a first plurality of staircase substructures 514 are formed. At step (b), a second etching operation is performed on at least a part of the first plurality of staircase substructures 514 to form the second plurality of staircase substructures 516. At step (c), a third etching operation is performed on at least a part of the second plurality of staircase substructures 516 to form the third plurality of staircase substructures 518. At step (d), a fourth etching operation is performed on at least a part of the third plurality of staircase substructures 518 to form the first staircase structure 512. It should be noted that although four etching operations are shown in FIG. 5B, any suitable number of etching operations can be performed to form the staircase structure. While the at least a part of the first deck is etched to form the first staircase structure 512, a part 520 of the first deck can remain unetched. A wall region can be formed based on the part 520 of the first deck in later operation(s).

Returning to FIG. 5A, after the first staircase structure 512 is formed, protective layers 508 are deposited on the first sacrificial layers 502. After the first staircase structure 512 is formed, the outer regions of the first stack 510 can be exposed, and each pair of first sacrificial layer 502 and first isolating layer 504 can form a staircase step. A protective layer 508 can then be deposited on a top surface of the staircase step. In some implementations, protective layer 508 can include polysilicon. Then, the first staircase structure 512 is covered by insulating structure 513 (e.g., corresponding to the insulating structure 130 of FIG. 1C).

FIG. 5C shows a structure 500c after a second stage of forming the semiconductor structure. The second stage includes, for example, forming (i) first gate line holes 524 (as shown in FIG. 5D) in first array region (e.g., corresponding to the array region 102 of FIGS. 1A-1B) and the first connection region (e.g., corresponding to the connection region 104 of FIGS. 1A-1B), (ii) first channel holes (not shown) in the first array region and the first connection region, and (iii) first contact holes 522 in the first connection region. The first gate line holes 524 can be used to form gate line slit structures (e.g., corresponding to the gate line slit structures 108 of FIGS. 1A-1B). The first channel holes can be used to form channel structures (e.g., corresponding to the channel structures 106 of FIGS. 1A-1B). The first contact holes 522 can be used to form contact structures (e.g., corresponding to the contact structures 112 of FIGS. 1A-1B). The first gate line holes 524, the first channel holes, and the first contact holes 522 extend through the first deck along the vertical direction.

In some implementations, forming the first gate line holes 524, the first channel holes, and the first contact holes 522 can include performing one or more etching operations to remove portions of the first stack 510 to form the first gate line holes 524, the first channel holes, and the first contact holes 522. In some implementations, removing portions of the first stack 510 includes removing portions of the insulating structure 513, the first sacrificial layer 502, the first isolating layer 504, the protective layer 508, and/or the semiconductor layer 506.

In some cases, the first gate line holes 524, the first channel holes, and the first contact holes 522 may have the same depth extending to the semiconductor layer 506. In some implementations, after the first gate line holes 524, the first channel holes, and the first contact holes 522 are formed, an oxidation operation can be performed to form an insulation layer on the exposed portions of the semiconductor layer 506. In some implementations, when the protective layer 508 includes polysilicon, the exposed surface of the protective layer 508 can also be oxidized.

In some cases, the first gate line holes 524, the first channel holes, and the first contact holes 522 are formed during a same first etching process. For example, the first gate line holes 524, the first channel holes, and the first contact holes 522 can be formed using one mask. By forming the first gate line holes, the first channel holes, and the first contact holes 522 together, the process steps can be significantly reduced, and the manufacturing cost can be lowered.

FIG. 5D shows a cross-sectional view of the structure 500c. FIG. 5D shows a first gate line hole 524 and a first contact hole 522. As shown in FIG. 5D, the first gate line hole 524 and the first contact hole 522 can have a same depth extending to the semiconductor layer 506.

FIG. 5E shows a structure 500e after a third stage of forming the semiconductor structure. As shown in FIG. 5E, after forming the first gate line hole 524 and the first contact hole 522, a first sacrificial filling 526 is formed in the first contact hole 522, and a second sacrificial filling 528 is formed in the first gate line hole 524. Although not shown in FIG. 5E, a third sacrificial filling can be formed in the first channel holes. In some implementations, the first sacrificial filling 526, the second sacrificial filling 528, and the third sacrificial filling are formed in the first contact hole 522, the first gate line hole 524, and the first channel holes together in a same deposition process.

In some implementations, after the operations described with respect to FIG. 5E, a second deck including a structure similar to the structure 500e of FIG. 5E can be formed over the first deck using similar operations as described with respect to FIGS. 5A-5E. In particular, the operations can include providing a second deck (not shown in FIG. 5A-5O) adjacent to the first deck along the vertical direction. The second deck includes a second stack of second sacrificial layers and second isolating layers extending along the first horizontal direction, the second sacrificial layers and the second isolating layers alternating with each other along the second horizontal direction. Providing the second deck can include depositing a second stack of second sacrificial layers and second isolating layers over the first stack 510 of first sacrificial layers 502 and first isolating layers 504. Then, at least a part of the second deck can be etched to form a second staircase structure. The second deck can include a second array region and a second connection region, where the second connection region includes the second staircase structure and is adjacent to the second array region along the first horizontal direction. After the second staircase structure is formed, the operations can include forming (i) second gate line holes in the second array region and the second connection region, (ii) second channel holes in the second array region and the second connection region, and (iii) second contact holes in the second connection region. The second gate line holes, the second channel holes, and the second contact holes extend through the second deck along the vertical direction. In some implementations, the second gate line holes, the second channel holes, and the second contact holes are formed during a same second etching process. The second gate line holes can be aligned with the first gate line holes, the second channel holes can be aligned with the first channel holes, and the second contact holes can be aligned with the first contact holes. Sacrificial fillings can be formed in the second gate line holes, the second channel holes, and the second contact holes. Similar operations can be used to form any suitable number of decks. A difference between forming the second or subsequent deck and the first deck is that, in some implementations, the second or subsequent deck does not include a semiconductor layer similar to the semiconductor layer 506.

Consequently, the techniques described herein enable to form staircase structure of each deck during the respective forming process of the corresponding deck. Compared to forming staircase structures after all decks are formed, the techniques described herein enables to form the staircase structures in some scenarios. These include cases where a staircase structure is adjacent to or has a gap with another staircase structure on the first direction. For example, the techniques described herein enables to form the second example staircase structures described with respect to FIGS. 3A-3C and the third example staircase structures described with respect to FIGS. 4A-4B.

In some implementations, after the plurality of decks are formed based on the descriptions described above, sacrificial material from the sacrificial layers (e.g., the first sacrificial layers and the second sacrificial layers) can be replaced by conductive material, and contact structures (e.g., corresponding to the contact structures 112 of FIGS. 1A-1B) can be formed based on operations described with respect to FIGS. 5F-5O.

As shown in FIG. 5F, first sacrificial filling 526 can be removed to expose first contact hole 522. In some implementations, in the operation of removing first sacrificial filling 526, portions of first sacrificial layers 502 can also be removed. In other words, protective layer 508 may extrude along the sidewalls of first contact hole 522, as shown in FIG. 5F. The extruding structure of protective layer 508 can form a specific shape of the topmost conductive layer in a later operation.

As shown in FIG. 5G, spacer layer 530 is formed on the sidewalls of first contact hole 522. In some implementations, spacer layer 530 can include silicon oxide. After forming spacer layer 530 on the sidewalls of first contact hole 522, a portion of protective layer 508 is above spacer layer 530, as shown in FIG. 5F. In other words, the extruding structure of protective layer 508 can cover the top surface of spacer layer 530.

As shown in FIG. 5H, a sacrificial structure 532 (e.g., a dielectric layer) is formed in first contact hole 522. In some implementations, sacrificial structure 532 can include one layer or multiple layers of polysilicon. In some implementations, sacrificial structure 532 may be formed in one or multiple deposition operations including, but not limited to, chemical vapor deposition (CVD), physical vapor deposition (PVD), atomic layer deposition (ALD), or any combination thereof.

Then, the first sacrificial layers 502 and protective layer 508 can be replaced with conductive layers 534 to form a stack having interleaved conductive layers 534 and first isolating layers 504. As shown in FIG. 5I, second sacrificial filling 528 is removed to expose first gate line hole 524. Then, as shown in FIG. 5J, a portion of first sacrificial layers 502 and a portion of first isolating layers 504 are removed along the sidewalls of first gate line hole 524. In other words, first gate line hole 524 can be widened in this operation. In some implementations, the widened first gate line hole 524 can be connected to other widened first gate line hole 524 along the X-direction. Gate line slit structure (e.g., corresponding to the gate line slit structure 108) can be formed in the widened first gate line hole 524 in a later operation. The gate line slit structure can be connected to other gate line slit structure along the X-direction in a later operation.

As shown in FIG. 5K, first sacrificial layers 502 are removed. As shown in FIG. 5L, protective layer 508 is removed. In some cases, the first sacrificial layers 502 and the protective layer 508 are removed in a same removal operation (e.g., the same etching operation). In other cases, the first sacrificial layers 502 and the protective layer 508 are removed in multiple removal operations (e.g., multiple etching operations). After removing the first sacrificial layers 502 and the protective layer 508, multiple cavities 538 are formed between first isolating layers 504.

As noted, a part of the first deck (e.g., the part 520 of FIG. 5B) remains unetched during the formation of the first staircase structure 512, where the part of the first deck includes a part of the first stack 510 of first sacrificial layers 502 and first isolating layers 504. During the operations of FIG. 5K, sacrificial material from sacrificial layers of the part of the first deck can be removed.

As shown in FIG. 5L, a topmost cavity 536 is formed between first isolating layer 504 and insulating structure 513. In some implementations, topmost cavity 536 has a first width W1 above first isolating layer 504 and a second width W2 above spacer layer 530. In some implementations, the first width W1 is greater than the second width W2.

As shown in FIG. 5M, conductive layers 534 are formed in topmost cavity 536 and cavities 538. As noted, cavities are formed in a part of the first deck (e.g., the part 520 of FIG. 5B), and conductive layers 534 can also be formed in these cavities to form a wall region.

As shown in FIG. 5N, gate line slit structure 540 is formed in first gate line hole 524 and sacrificial structure 532 is removed to expose first contact hole 522. In some implementations, an etching operation is performed to clean the sidewalls of first gate line hole 524 and then gate line slit structure 540 is formed in first gate line hole 524. Because first gate line hole 524 has been widened (as shown in FIG. 5J), in some implementations, gate line slit structure 540 formed in the widened first gate line hole 524 can be connected to other gate line slit structure 540 along the X-direction. In some implementations, sacrificial structure 532 is removed by performing an etching operation to expose first contact hole 522.

As shown in FIG. 5O, a portion of spacer layer 530 along the sidewalls of the first contact hole 522 is removed. In some implementations, a portion of spacer layer 530 and a portion of insulating structure 513 are removed. Then, contact structure 542 (e.g., corresponding to the contact structure 112 of FIGS. 1A-1B) is formed in the first contact hole 522. Contact structure 542 can include conductive materials including, but not limited to, W, Co, Cu, Al, polysilicon, doped silicon, silicide, or any combination thereof. In some implementations, the contact structure 542 and the conductive layer 534 can be formed by using the same material. A top conductive layer 534 can be in contact with contact structure 542. In some implementations, spacer layer 530 is formed between contact structure 542 and conductive layers 534. Spacer layer 530 extends along the Z-direction and can insulate contact structure 542 and conductive layers 534.

By forming contact structure 542, gate line slit structure 540, and/or the channel structure with the above-mentioned process, the formation processes of the channel structures, the gate line slit structures, and the contact structures are merged, and all deep hole etching processes can be completed in a simplified operation. Hence, the manufacturing process can be simplified, and the manufacturing cost can be reduced.

Further, as noted, in the second example staircase structures described with respect to FIGS. 3A-3C and the third example staircase structures described with respect to FIGS. 4A-4B, a stack of sacrificial layers and isolating layers can be deposited above a staircase structure (e.g., as shown in FIG. 3C and FIG. 4B). In such structures, holes (e.g., including the gate line holes, the channel holes, and the contact holes) may not be formable after the sacrificial material of the sacrificial layers is replaced with the conductive material, particularly because contact holes may not be able to extend through conductive layers above the staircase structure. The techniques described with respect to FIGS. 5A-5O enable to form the holes (e.g., the operations described with respect to FIGS. 5C-5D) before replacing the sacrificial material of the sacrificial layers with the conductive material (e.g., the operations described with respect to FIGS. 5K-5M). Accordingly, the techniques described with respect to FIGS. 5A-5O enable to fabricate the second example staircase structures described with respect to FIGS. 3A-3C and the third example staircase structures described with respect to FIGS. 4A-4B.

Although FIGS. 5A-5O describe that the formation of the contact structure 542 (e.g., the operations described with respect to FIGS. 5N-5O) occurs after replacing the sacrificial material of the sacrificial layers with the conductive material (e.g., the operations described with respect to FIGS. 5K-5M), in some implementations, the formation of the contact structure 542 can occur before replacing the sacrificial material of the sacrificial layers with the conductive material.

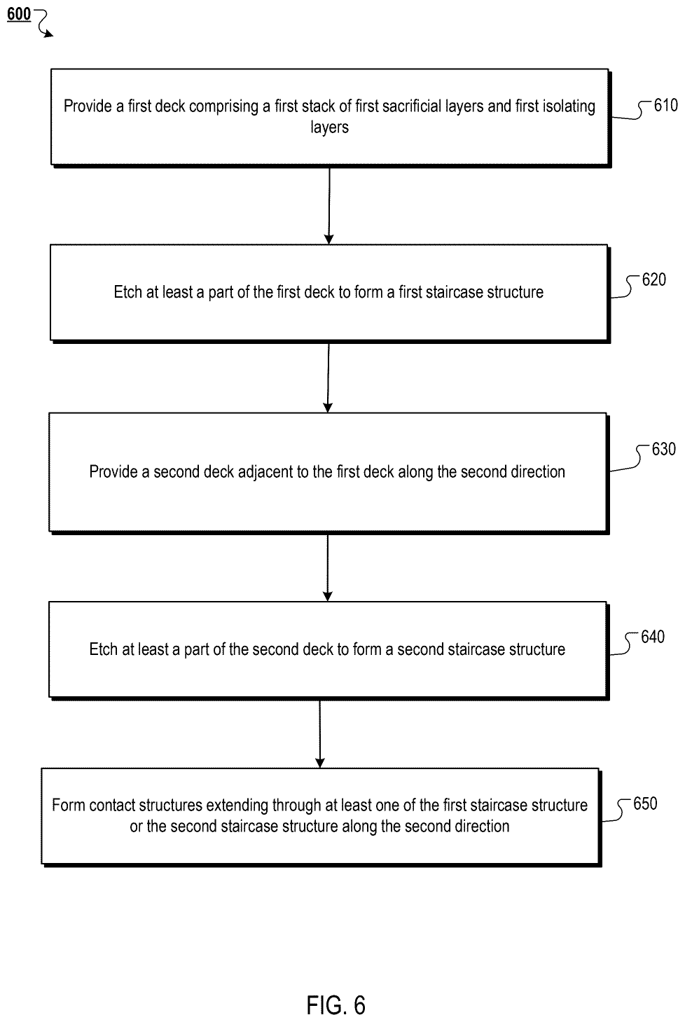

FIG. 6 is a flow chart of an example process 600 of forming a semiconductor structure, according to some aspects of the present disclosure. The semiconductor structure can be similar to, or same as, the semiconductor structure 100A/3D semiconductor structure 100B of FIGS. 1A-1B (or a part of the semiconductor structure 100A/3D semiconductor structure 100B), the semiconductor structure 200 of FIGS. 2A-2C (or a part of the semiconductor structure 200), the semiconductor structure 300 of FIGS. 3A-3C (or a part of the semiconductor structure 300), or the semiconductor structure 400 of FIGS. 4A-4B (or a part of the semiconductor structure 400). The example process 600 can be described in view of FIGS. 1-5. The example process 600 can include the fabrication process of forming the semiconductor structure in FIGS. 1A-1B, FIGS. 2A-2C, FIGS. 3A-3C, or FIGS. 4A-4B. The example process 600 includes steps that can be performed with any suitable order and/or any combination.

At step 610, a first deck including a first stack (e.g., the stack 115 of FIG. 1C or the first stack 510 of FIG. 5A) of first sacrificial layers (e.g., the first sacrificial layers 502 of FIG. 5A) and first isolating layers (e.g., the first isolating layers 504 of FIG. 5A) extending along a first direction (e.g., the X direction) is provided, the first sacrificial layers and the first isolating layers alternating with each other along a second direction (e.g., the Z direction) perpendicular to the first direction. In some implementations, providing the first deck includes providing a semiconductor layer (e.g., the semiconductor layer 114 of FIG. 1C or the semiconductor layer 506 of FIG. 5A), and depositing the first stack of first sacrificial layers and first isolating layers over the semiconductor layer.

At step 620, at least a part of the first deck can be etched to form a first staircase structure (e.g., the first staircase structure 512 of FIG. 5A). In some examples, the first staircase structure includes a staircase step, and the example process 600 includes depositing a protective layer (e.g., protective layers 508 of FIG. 5A) on a top surface of the staircase step.

In some implementations, the first deck includes a first array region (e.g., array region 102 of FIGS. 1A-1B, the array region 222 of FIG. 2C, the array region 322 of FIG. 3C, or the array region 422 of FIG. 4B) and a first connection region (e.g., the connection region 202 of FIGS. 2A-2C, the connection region 302 of FIGS. 3A-3C, or the connection region 402 of FIGS. 4A-4B). The first connection region includes the first staircase structure (e.g., the staircase structure 208 of FIGS. 2A-2C, the staircase structures 308 of FIGS. 3A-3C, or the staircase structures 408 of FIGS. 4A-4B) and is adjacent to the first array region along the first direction. The example process 600 includes: forming (i) first gate line holes (e.g., first gate line holes 524 of FIG. 5D) in the first array region and the first connection region, (ii) first channel holes in the first array region and the first connection region, and (iii) first contact holes (e.g., first contact holes 522 of FIG. 5D) in the first connection region, where the first gate line holes, the first channel holes, and the first contact holes extend through the first deck along the second direction, and where the first gate line holes, the first channel holes, and the first contact holes are formed during a same first etching process.

In some cases, etching at least a part of the first deck to form the first staircase structure includes: etching a first part of the first deck to form the first staircase structure, while a second part of the first deck (e.g., the part 520 of FIG. 5B) remains unetched, where the second part of the first deck is adjacent to the first part of the first deck along a third direction (e.g., the Y direction) perpendicular to the first direction and the second direction, and where the second part of the first deck includes a part of the first stack of first sacrificial layers and first isolating layers. Sacrificial material can be removed from sacrificial layers of the second part of the first deck. At least one conductive material can be deposited in the second part of the first deck to form a wall region (e.g., the wall region 220 of FIGS. 2A-2B or the wall region 320 of FIGS. 3A-3B).

At step 630, a second deck adjacent to the first deck along the second direction can be provided, the second deck including a second stack of second sacrificial layers and second isolating layers extending along the first direction, the second sacrificial layers and the second isolating layers alternating with each other along the second direction. In some cases, providing the second deck includes, after the first etching process, depositing a second stack of second sacrificial layers and second isolating layers over the first stack of first sacrificial layers and first isolating layers.

At step 640, at least a part of the second deck can be etched to form a second staircase structure (e.g., the staircase structure 212 of FIGS. 2A-2C, the staircase structures 312 of FIGS. 3A-3B, or the staircase structures 412 of FIG. 4A). In some implementations, the second deck includes a second array region and a second connection region, where the second connection region includes the second staircase structure and is adjacent to the second array region along the first direction, and where the method includes, after providing the second deck, forming (i) second gate line holes in the second array region and the second connection region, (ii) second channel holes in the second array region and the second connection region, and (iii) second contact holes in the second connection region, where the second gate line holes, the second channel holes, and the second contact holes extend through the second deck along the second direction, and where the second gate line holes, the second channel holes, and the second contact holes are formed during a same second etching process. In some cases, the first staircase structure is adjacent to or has a gap with the second staircase structure on the first direction.

In some implementations, example process 600 includes, after forming the second gate line holes, the second channel holes, and the second contact holes, removing sacrificial material from the first sacrificial layers and the second sacrificial layers, and depositing conductive material in the first sacrificial layers and the second sacrificial layers to form first conductive layers (e.g., conductive layers 534 of FIGS. 5N-5O) and second conductive layers, respectively.

At step 650, contact structures (e.g., the contact structure 542 of FIG. 5O) extending through at least one of the first staircase structure or the second staircase structure can be formed along the second direction. In some implementations, forming the contact structures extending through at least one of the first staircase structure or the second staircase structure includes: forming first contact structures (e.g., the contact structures 224 of FIG. 2C) and second contact structures (e.g., the contact structures 224 of FIG. 2C, the contact structures 324 of FIG. 3C, or the contact structures 424 of FIG. 4B), where the first contact structures extend through the first staircase structure and do not extend through the second staircase structure, and where the second contact structures extend through the second staircase structure and do not extend through the first staircase structure. In some cases, the first contact structures extend through the second conductive layers and the second isolating layers, and the second contact structures extend through the first conductive layers and the first isolating layers; or the first contact structures extend through an insulating structure (e.g., the insulating structure 228 of FIG. 2C) included in the second deck, and the second contact structures extend through the first conductive layers and the first isolating layers

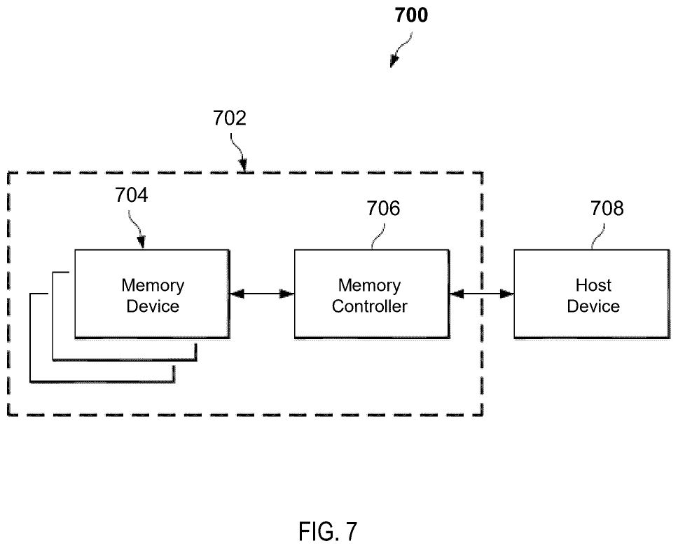

FIG. 7 illustrates a block diagram of a system 700 having one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein, such as 3D memory device depicted in FIGS. 1A-1B, 3D memory device based on the semiconductor structure 200 of FIGS. 2A-2E, or 3D memory device based on the semiconductor structure 300 of FIGS. 3A-3D. In some implementations, a 3D memory device 704 includes a NAND Flash memory. Memory controller 706 (a.k.a., a controller circuit) is coupled to 3D memory device 704 and host device 708. Consistent with implementations of the present disclosure, 3D memory device 704 can include a plurality of conductive interconnections through a cover layer that are in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of channel structures via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single 3D memory device 704 may be integrated into a memory system 702. Memory system 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage semiconductor layer, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “semiconductor layer” refers to a material onto which subsequent material layers are added. The semiconductor layer includes a “top” surface and a “bottom” surface. The top surface of the semiconductor layer is typically where a semiconductor device is formed, and therefore the semiconductor device is formed at a top side of the semiconductor layer unless stated otherwise. The bottom surface is opposite to the top surface and therefore a bottom side of the semiconductor layer is opposite to the top side of the semiconductor layer. The semiconductor layer itself can be patterned. Materials added on top of the semiconductor layer can be patterned or can remain unpatterned. Furthermore, the semiconductor layer can include a wide array of semiconductor materials, such as silicon, germanium, gallium arsenide, indium phosphide, etc. Alternatively, the semiconductor layer can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the semiconductor layer and the top side is relatively away from the semiconductor layer. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A semiconductor layer can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+0.10%, .+0.20%, or +0.30% of the value).

In the present disclosure, the term “horizontal/horizontally/lateral/laterally” means nominally parallel to a lateral surface of a semiconductor layer, and the term “vertical” or “vertically” means nominally perpendicular to the lateral surface of a semiconductor layer.

As used herein, the term “3D memory” refers to a three-dimensional (3D) semiconductor device with vertically oriented strings of memory cell transistors (referred to herein as “memory strings,” such as NAND strings) on a laterally-oriented semiconductor layer so that the memory strings extend in the vertical direction with respect to the semiconductor layer.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first deck comprising a first staircase structure extending along a first direction; and
a second deck adjacent to the first deck along a second direction perpendicular to the first direction, wherein the second deck comprises a second staircase structure, and wherein the first staircase structure is adjacent to or has a gap with the second staircase structure on the first direction.

2. The semiconductor device of claim 1, wherein the second deck comprises a stack of conductive layers and isolating layers alternating with each other along the second direction, and the stack of conductive layers and isolating layers is adjacent to the first staircase structure along the second direction.

3. The semiconductor device of claim 1, wherein the first direction and the second direction define a first plane, wherein a first area is a projection of the first staircase structure on the first plane, wherein a second area is a projection of the second staircase structure on the first plane, and wherein the first area has the same shape as the second area.

4. The semiconductor device of claim 3, wherein each of the first area and the second area is a V-shaped area.

5. The semiconductor device of claim 3, wherein the first staircase structure comprises a first staircase substructure and a second staircase substructure, the first staircase substructure comprises first staircase steps descending along the first direction, and the second staircase substructure comprises second staircase steps ascending along the first direction.

6. The semiconductor device of claim 5, wherein the first deck comprises an array region, a wall region, and a connection region comprising the first staircase structure, wherein the wall region is adjacent to the connection region along a third direction perpendicular to the first direction and the second direction, and wherein the second staircase steps ascending along the first direction are coupled to the array region via the wall region.

7. The semiconductor device of claim 6, wherein the first deck comprises a third staircase structure, and the third staircase structure is adjacent to the first staircase structure on the first direction, and wherein the second deck comprises a fourth staircase structure, and the second staircase structure has a gap with the fourth staircase structure on the first direction.

8. The semiconductor device of claim 7, wherein a third area is a projection of the third staircase structure on the first plane, wherein a fourth area is a projection of the fourth staircase structure on the first plane, and wherein the third area has the same shape as the fourth area.

9. The semiconductor device of claim 8, wherein each of the first staircase structure and the third staircase structure is in between the second staircase structure and the fourth staircase structure along the first direction.

10. The semiconductor device of claim 1, wherein the semiconductor device comprises a contact structure having a first segment in the first deck and a second segment in the second deck, and wherein each of the first segment and the second segment has a first diameter at the top and a second diameter at the bottom along the second direction, and the first diameter is greater than the second diameter.

11. A method, comprising:
providing a first deck comprising a first stack of first sacrificial layers and first isolating layers extending along a first direction, the first sacrificial layers and the first isolating layers alternating with each other along a second direction perpendicular to the first direction;
etching at least a part of the first deck to form a first staircase structure;
providing a second deck adjacent to the first deck along the second direction, the second deck comprising a second stack of second sacrificial layers and second isolating layers extending along the first direction, the second sacrificial layers and the second isolating layers alternating with each other along the second direction;
etching at least a part of the second deck to form a second staircase structure; and
forming contact structures extending through at least one of the first staircase structure or the second staircase structure along the second direction.

12. The method of claim 11, wherein the first staircase structure is adjacent to or has a gap with the second staircase structure on the first direction.

13. The method of claim 11, wherein the first staircase structure comprises a staircase step, and wherein the method comprises:
depositing a protective layer on a top surface of the staircase step.

14. The method of claim 11, wherein the first deck comprises a first array region and a first connection region, wherein the first connection region comprises the first staircase structure and is adjacent to the first array region along the first direction, and wherein the method comprises:
forming (i) first gate line holes in the first array region and the first connection region, (ii) first channel holes in the first array region and the first connection region, and (iii) first contact holes in the first connection region, wherein the first gate line holes, the first channel holes, and the first contact holes extend through the first deck along the second direction, and wherein the first gate line holes, the first channel holes, and the first contact holes are formed during a same first etching process.

15. The method of claim 14, wherein the second deck comprises a second array region and a second connection region, wherein the second connection region comprises the second staircase structure and is adjacent to the second array region along the first direction, and wherein the method comprises, after providing the second deck:
forming (i) second gate line holes in the second array region and the second connection region, (ii) second channel holes in the second array region and the second connection region, and (iii) second contact holes in the second connection region, wherein the second gate line holes, the second channel holes, and the second contact holes extend through the second deck along the second direction, and wherein the second gate line holes, the second channel holes, and the second contact holes are formed during a same second etching process.

16. The method of claim 15, comprising, after forming the second gate line holes, the second channel holes, and the second contact holes:
removing sacrificial material from the first sacrificial layers and the second sacrificial layers; and
depositing conductive material in the first sacrificial layers and the second sacrificial layers to form first conductive layers and second conductive layers, respectively.

17. The method of claim 16, wherein forming the contact structures extending through at least one of the first staircase structure or the second staircase structure comprises:
forming first contact structures and second contact structures, wherein the first contact structures extend through the first staircase structure and do not extend through the second staircase structure, and wherein the second contact structures extend through the second staircase structure and do not extend through the first staircase structure.

18. The method of claim 17, wherein:
the first contact structures extend through the second conductive layers and the second isolating layers, and the second contact structures extend through the first conductive layers and the first isolating layers; or
the first contact structures extend through an insulating structure comprised in the second deck, and the second contact structures extend through the first conductive layers and the first isolating layers.

19. The method of claim 11, wherein etching at least a part of the first deck to form the first staircase structure comprises:
etching a first part of the first deck to form the first staircase structure, while a second part of the first deck remains unetched, wherein the second part of the first deck is adjacent to the first part of the first deck along a third direction perpendicular to the first direction and the second direction, and wherein the second part of the first deck comprises a part of the first stack of first sacrificial layers and first isolating layers;
removing sacrificial material from sacrificial layers of the second part of the first deck; and
depositing at least one conductive material in the second part of the first deck to form a wall region.

20. A system, comprising:
a semiconductor device comprising:
a first deck comprising a first staircase structure, wherein the first staircase structure has a first starting point and a first ending point on a first direction, and wherein the first starting point and the first ending point define a first interval; and
a second deck adjacent to the first deck along a second direction perpendicular to the first direction, wherein the second deck comprises a second staircase structure, the second staircase structure has a second starting point and a second ending point on the first direction, and the second starting point and the second ending point define a second interval, and wherein the first interval is adjacent to or has a gap with the second interval; and
a memory controller electrically connected to the semiconductor device, wherein the memory controller is configured to control the semiconductor device.
